(19) United States
(12) Patent Application Publication
(10) Pub. No.: US 2026/0256009 A1
(43) Pub. Date: Aug. 27, 2026

(54) SEMICONDUCTOR PACKAGE INCLUDING A POST HAVING DIFFERENT WIDTHS AND METHOD OF MANUFACTURING THE SAME

(71) Applicant: Samsung Electronics Co., Ltd., Suwon-si (KR)

(72) Inventors: Mina Heo, Suwon-si (KR); Seunghun Chae, Suwon-si (KR); Unbyoung Kang, Suwon-si (KR); Dowan Kim, Suwon-si (KR)

(21) Appl. No.: 19/448,273

(22) Filed: Jan. 14, 2026

(30) Foreign Application Priority Data
Feb. 26, 2025 (KR) 10-2025-0024951

(51) Int. Cl. H10W 72/00; H10W 90/00; H10W 90/20; H10W 74/10

(52) U.S. Cl. CPC H10W 72/823; H10W 90/297; H10W 90/401; H10W 90/722; H10W 90/724; H10W 90/7295; H10W 74/111

(57) ABSTRACT

A semiconductor package includes a lower redistribution structure including a lower redistribution layer; a chip structure on the lower redistribution structure; an encapsulant covering the chip structure; a post penetrating the encapsulant; and external connection bumps disposed below the lower redistribution structure and electrically connected to the lower redistribution layer, wherein post includes a lower metal layer on the lower redistribution layer of the lower redistribution structure; and an upper metal layer on the lower metal layer, wherein a width of the upper metal layer increases in a vertical direction, and a surface of the upper metal layer has a plurality of grooves, wherein a width of a lower region of the upper metal layer is smaller than a width of an upper region of the lower metal layer, and wherein at least a portion of the encapsulant fills the plurality of grooves of the upper metal layer.

### CROSS-REFERENCE TO RELATED APPLICATION(S)

This application claims benefit of priority under 35 U.S.C. § 119 to Korean Patent Application No. 10-2025-0024951, filed on February 26, 2025, in the Korean Intellectual Property Office, the disclosure of which is incorporated herein by reference in its entirety.

### BACKGROUND

Example embodiments of the present disclosure relate to a semiconductor package and a method of manufacturing the same.

Recently, high performance, high capacity, and high reliability have been required in semiconductor packages mounted in electronic devices. Accordingly, development of a semiconductor package including at least one semiconductor chip embedded therein has been undertaken.

### SUMMARY

An example embodiment of the present disclosure is to provide a semiconductor package having improved reliability and a method of manufacturing the same.

According to an example embodiment of the present disclosure, a semiconductor package includes a lower redistribution structure including a lower redistribution layer; a lower chip structure on the lower redistribution structure; an encapsulant covering the lower chip structure; a post penetrating the encapsulant and connected to the lower redistribution layer; and external connection bumps disposed below the lower redistribution structure and electrically connected to the lower redistribution layer, wherein the post includes a first portion disposed on the lower redistribution layer of the lower redistribution structure and extending from the lower redistribution layer in a vertical direction; and a second portion on the first portion, wherein a width of a lower region of the second portion is smaller than a width of an upper region of the first portion, and wherein a surface roughness of a side surface of the second portion is greater than a surface roughness of a side surface of the first portion.

According to an example embodiment of the present disclosure, a semiconductor package includes a lower redistribution structure including a lower redistribution layer; a chip structure on the lower redistribution structure; an encapsulant covering the chip structure; an upper redistribution structure disposed on the encapsulant, and including an upper insulating layer, and an upper redistribution layer and an upper redistribution via in the upper insulating layer; a plurality of posts penetrating the encapsulant and electrically connecting the lower redistribution layer to the upper redistribution layer; and external connection bumps disposed below the lower redistribution structure and electrically connected to the lower redistribution layer, wherein each of the plurality of posts includes a lower metal layer on the lower redistribution layer of the lower redistribution structure; and an upper metal layer disposed between the lower metal layer and the upper redistribution via, and electrically connecting the lower metal layer to the upper redistribution via, wherein a width of the upper metal layer increases in a vertical direction, and a surface of the upper metal layer has a plurality of grooves, wherein a width of a lower region of the upper metal layer is smaller than a width of an upper region of the lower metal layer, and wherein at least a portion of the encapsulant fills the plurality of grooves of the upper metal layer.

According to an example embodiment of the present disclosure, a semiconductor package includes a lower redistribution structure including a lower redistribution layer; a chip structure on the lower redistribution structure; an upper redistribution structure disposed on the chip structure and including an upper redistribution layer; at least one post electrically connecting the lower redistribution layer to the upper redistribution layer on at least one side of the chip structure; and an encapsulant covering the chip structure and a plurality of posts between the lower redistribution structure and the upper redistribution structure, wherein the at least one post includes a lower metal layer on the lower redistribution layer of the lower redistribution structure; and an upper metal layer disposed between the lower metal layer and the upper redistribution layer, and electrically connecting the lower metal layer to the upper redistribution layer, wherein a surface of the upper metal layer has a plurality of grooves, and wherein the encapsulant includes a first portion covering a back surface of the chip structure; and a second portion extending in a horizontal direction from at least a portion of the first portion, filling the plurality of grooves of the upper metal layer of the post, covering an edge of an upper surface of the lower metal layer of the post, and surrounding at least a portion of a side surface of the lower metal layer of the post.

According to an example embodiment of the present disclosure, a method of manufacturing a semiconductor package includes providing a lower redistribution structure including a lower redistribution layer; forming a chip structure on the lower redistribution structure; forming a post electrically connected to the lower redistribution layer of the lower redistribution structure on at least one side of the chip structure; forming an encapsulant on the lower redistribution structure, forming an encapsulant surrounding the post and covering the chip structure on the lower redistribution structure; and forming an upper redistribution structure including an upper redistribution layer electrically connected to the post on the encapsulant, wherein the post includes a lower metal layer on the lower redistribution layer of the lower redistribution structure; and an upper metal layer between the lower metal layer and the upper redistribution layer, wherein a width of a lower surface of the upper metal layer is smaller than a width of an upper surface of the lower metal layer, and wherein a width of the upper metal layer increases in a direction away from an upper surface of the lower metal layer.

The forming the posts may include forming a first photoresist layer covering the lower redistribution structure and the chip structure; forming a first opening penetrating the first photoresist layer, and forming the lower metal layer in the first opening; forming a second photoresist layer on the first photoresist layer and the lower metal layer; and forming a second opening penetrating the second photoresist layer, and forming the upper metal layer in the second opening.

The first photoresist layer may include a negative photoresist, and the second photoresist layer may include a positive photoresist.

Surface roughness of the sidewall of the second opening may be greater than surface roughness of the sidewall of the first opening.

The method may further include removing the first and second photoresist layers before the forming the encapsulant, and an edge of an upper surface of the upper metal layer is exposed by removing the first and second photoresist layers.

The method may further include planarizing upper surfaces of the first photoresist layer and the lower metal layer before the forming the second photoresist.

A ratio of a width of the upper surface of the upper metal layer to a width of the lower surface of the upper metal layer may be in a range of about 1.5 to about 2.0.

An angle formed by an upper surface of the upper metal layer and a side surface of the upper metal layer may be in a range of about 30° to about 60°.

The chip structure may include a base chip including connection pads electrically connected to the lower redistribution layer, upper pads opposing the connection pads, and through-vias electrically connecting the connection pads to the upper pads; and at least one stack chip disposed on the base chip, electrically connected to the base chip, and having a lower surface on which lower pads are disposed.

The method may further include forming external connection bumps in a lower portion of the lower redistribution structure.

### BRIEF DESCRIPTION OF DRAWINGS

The above and other aspects, features, and advantages of the present disclosure will be more clearly understood from the following detailed description, taken in combination with the accompanying drawings, in which:

FIG. 1A is a cross-sectional diagram illustrating a semiconductor package according to an example embodiment of the present disclosure;

FIG. 1B is a plan diagram taken along line I-I’ in FIG. 1A;

FIG. 1C is an enlarged diagram illustrating region ‘A’ in FIG. 1A;

FIG. 2 is a diagram illustrating a modified example in an example embodiment;

FIG. 3A is a cross-sectional diagram illustrating a semiconductor package according to an example embodiment of the present disclosure;

FIG. 3B is a plan diagram taken along line I-I’ in FIG. 3A;

FIG. 3C is an enlarged diagram illustrating region ‘B’ in FIG. 3A;

FIG. 4 is a diagram illustrating a modified example according to an example embodiment of the present disclosure;

FIG. 5 is a cross-sectional diagram illustrating a semiconductor package according to an example embodiment of the present disclosure;

FIG. 6 is a cross-sectional diagram illustrating a semiconductor package according to an example embodiment of the present disclosure;

FIG. 7 is a cross-sectional diagram illustrating a semiconductor package according to an example embodiment of the present disclosure;

FIG. 8 is a cross-sectional diagram illustrating a semiconductor package according to an example embodiment of the present disclosure;

FIG. 9 is a cross-sectional diagram illustrating a semiconductor package according to an example embodiment of the present disclosure;

FIGS. 10A to 10G are cross-sectional diagrams illustrating processes of manufacturing a semiconductor package according to an example embodiment of the present disclosure; and

FIGS. 11A to 11G are cross-sectional diagrams illustrating processes of manufacturing a semiconductor package according to an example embodiment of the present disclosure.

### DETAILED DESCRIPTION

Hereinafter, embodiments of the present disclosure will be described as below with reference to the accompanying drawings. Like reference characters refer to like elements throughout.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

Terms such as “same,” “equal,” “planar,” or “coplanar,” as used herein when referring to orientation, layout, location, shapes, sizes, amounts, or other measures do not necessarily mean an exactly identical orientation, layout, location, shape, size, amount, or other measure, but are intended to encompass nearly identical orientation, layout, location, shapes, sizes, amounts, or other measures within acceptable variations that may occur, for example, due to manufacturing processes. The term “substantially” may be used herein to emphasize this meaning, unless the context or other statements indicate otherwise. For example, items described as “substantially the same,” “substantially equal,” or “substantially planar,” may be exactly the same, equal, or planar, or may be the same, equal, or planar within acceptable variations that may occur, for example, due to manufacturing processes.

In example embodiments, the terms such as “upper,” “upper portion,” “upper surface,” “lower,” “lower portion,” “lower surface,” “side surface,” “upper end,” or the like, are based on the drawings unless otherwise indicated. The terms such as “upper portion,” “intermediate portion,” and “lower portion” may also be replaced with other terms, such as “first,” “second” and “third,” to describe elements in the example embodiments. The terms “first,” “second,” and the like may be used to distinguish one element from the other, and may not limit a sequence and/or an importance, or others, in relation to the elements. In some cases, a first element may be referred to as a second element, and similarly, a second element may be referred to as a first element without departing from the scope of rights of the example embodiments.

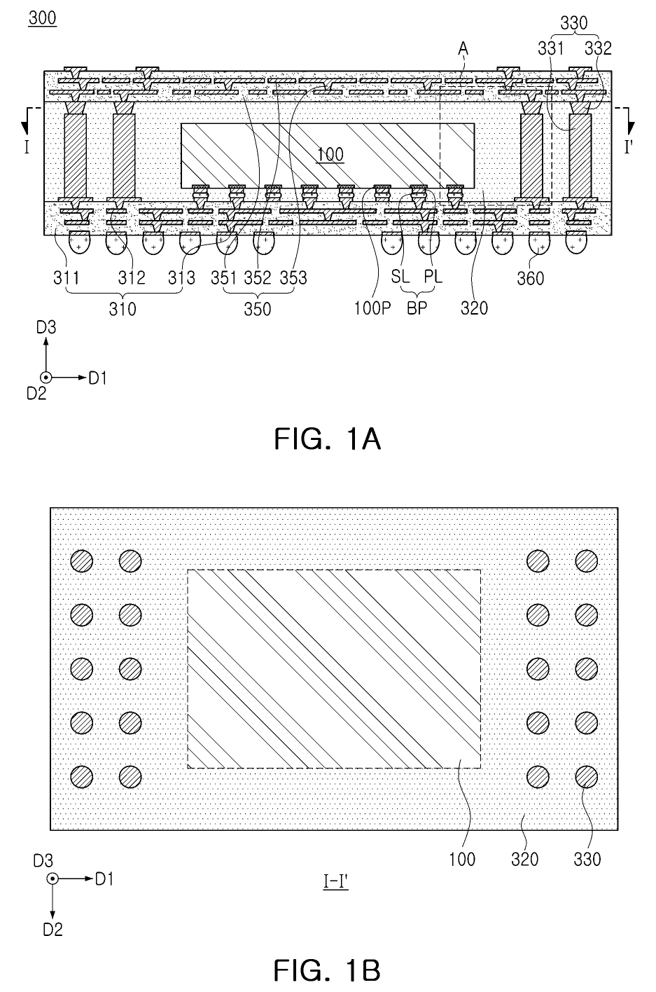

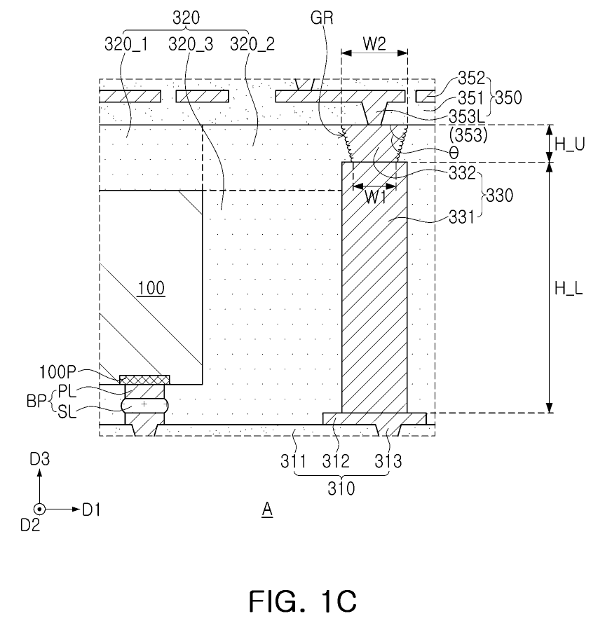

FIG. 1A is a cross-sectional diagram illustrating a semiconductor package according to an example embodiment. FIG. 1B is a plan diagram taken along line I-I’ in FIG. 1A. FIG. 1C is an enlarged diagram illustrating region ‘A’ in FIG. 1A.

Referring to FIGS. 1A to 1C, a semiconductor package 300 in an example embodiment may include a lower chip structure 100, a lower redistribution structure 310, a plurality of posts 330, an encapsulant 320, and an upper redistribution structure 350. In an example embodiment, the lower chip structure 100 and the lower redistribution structure 310 may be referred to as a “chip structure” and a “redistribution structure,” respectively.

The lower chip structure 100 may include first connection terminals 100P disposed on the lower redistribution structure 310 and electrically connected to the lower redistribution layer 312. The first connection terminals 100P may be connected to the lower redistribution layer 312 through connection bumps BP disposed between the lower chip structure 100 and the lower redistribution structure 310. Lower surfaces of the first connection terminals 100P may be coplanar with a lower surface of the lower chip structure 100. The connection bumps BP may include a pillar portion PL in contact with the first connection terminals 100P and a solder portion SL disposed below the pillar portion PL. The pillar portion PL may include copper (Cu) or an alloy of copper (Cu), and the solder portion SL may include a low-melting point metal, for example, tin (Sn) or an alloy including tin (Sn). In example embodiments, the connection bumps BP may include only one of the pillar portion PL and the solder portion SL.

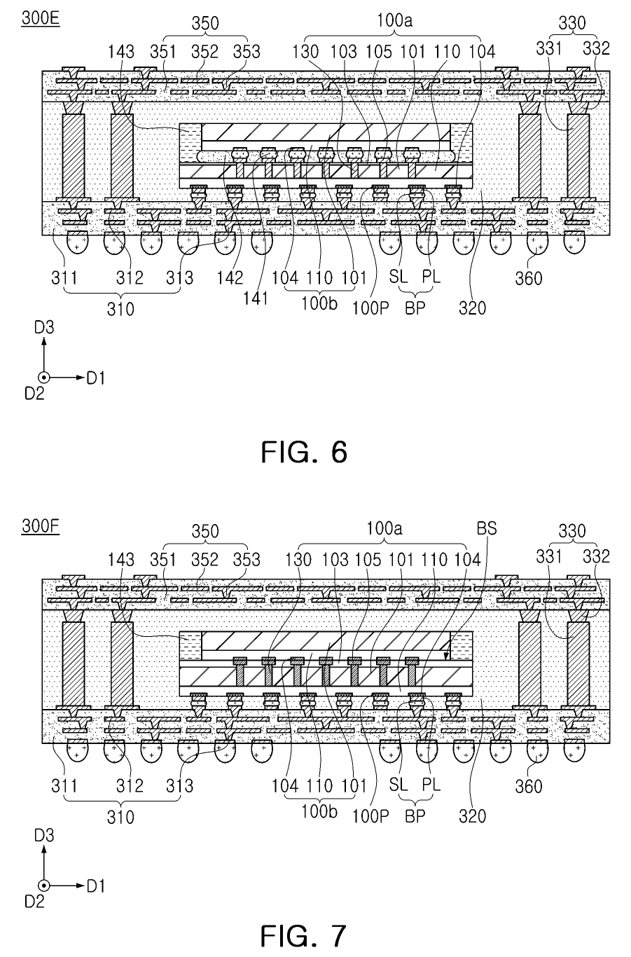

The lower chip structure 100 may include a semiconductor wafer and an integrated circuit (IC) formed of a semiconductor element such as silicon, germanium, or a compound semiconductor such as silicon carbide (SiC), gallium arsenide (GaAs), indium arsenide (InAs), and indium phosphide (InP). The lower chip structure 100 may be configured as a bare semiconductor chip without a bump or an interconnection layer, but an example embodiment thereof is not limited thereto, and the lower chip structure 100 may also be configured as a packaged type semiconductor chip. The integrated circuit may be implemented as a logic circuit (or ‘logic chip’) such as a central processor (CPU), a graphics processor (GPU), a filled programmable gate array (FPGA), an application processor (AP), a digital signal processor, an encryption processor, a microprocessor, a microcontroller, an analog-to-digital converter, an application-specific IC (ASIC), or a memory circuit (or ‘memory chip’) including a volatile memory such as dynamic RAM (DRAM), static random access memory (SRAM), and a nonvolatile memory such as phase change RAM (PRAM), magnetic RAM (MRAM), and resistive RAM (RRAM), and flash memory. In example embodiments, the lower chip structure 100 may be a package structure including a plurality of semiconductor chips, which will be described later with reference to FIGS. 6 and 7.

The lower redistribution structure 310 may be a support substrate on which the lower chip structure 100 is mounted, and may include a lower insulating layer 311, lower redistribution layers 312, and lower redistribution vias 313.

The lower insulating layer 311 may be formed of or include an insulating resin. The insulating resin may include a thermosetting resin such as an epoxy resin, a thermoplastic resin such as a polyimide, or a resin impregnated with an inorganic filler, for example, prepreg, Ajinomoto build-up film (ABF), FR-4, and bismaleimide-triazine (BT). For example, the lower insulating layer 311 may be formed of or include a photosensitive resin such as photoimageable dielectric (PID). The lower insulating layer 311 may include a plurality of insulating layers (not illustrated) stacked in the vertical direction D3. Depending on processes, a boundary between the plurality of insulating layers (not illustrated) may not be distinct.

The lower redistribution layer 312 may be disposed on and in the lower insulating layer 311 and may redistribute the first connection terminal 100P of the lower chip structure 100. The lower redistribution layer 312 may include a metal including, for example, copper (Cu), aluminum (Al), silver (Ag), tin (Sn), gold (Au), nickel (Ni), lead (Pb), titanium (Ti), or an alloy thereof. The lower redistribution layer 312 may perform various functions depending on a design. For example, the lower redistribution layer 312 may include a ground pattern, a power pattern, and a signal pattern. Here, the signal pattern may be defined as a transmission path of various signals, for example, a data signal, and may exclude the ground pattern, the power pattern, or the like. The lower redistribution layer 312 may include more or fewer redistribution layers than the example illustrated in the diagram. The lower redistribution layer 312 may include pads in contact with the connection bumps BP and the plurality of posts 330.

The lower redistribution via 313 may extend in the lower insulating layer 311 and may be electrically connected to the lower redistribution layer 312. For example, the lower redistribution via 313 may interconnect lower redistribution layers 312 of different levels. The lower redistribution via 313 may include a signal via, ground via, and power via. The lower redistribution via 313 may include a metal material, for example, copper (Cu), aluminum (Al), silver (Ag), tin (Sn), gold (Au), nickel (Ni), lead (Pb), titanium (Ti), or an alloy thereof. The lower redistribution via 313 may be a filled via in which metal material is filled in the via-hole or a conformal via in which a metal material extends along an inner wall of the via-hole.

The external connection bumps 360 may be disposed below the lower redistribution structure 310. The external connection bumps 360 may be electrically connected to the lower redistribution layer 312. In example embodiments, the external connection bumps 360 may contact lower surfaces of lowermost redistribution layer of the lower redistribution layer 312. The semiconductor package 300 may be connected to an external device such as a module substrate, a system board, or the like, through the external connection bumps 360. In example embodiments, the external connection bumps 360 may have a combination of a pillar (or underbump metal) and a ball. The pillar may include copper (Cu) or an alloy of copper (Cu), and the ball may include a low melting point metal, for example, tin (Sn) or an alloy including tin (Sn) (e.g., Sn-Ag-Cu). In example embodiments, the external connection bumps 360 may include only a pillar or only a ball. In example embodiments, a resist layer protecting the external connection bumps 360 from physical and chemical damage may be formed on a lower surface of the lower redistribution structure 310.

A plurality of posts 330 may be disposed on at least one side of the lower chip structure 100 and may penetrate the encapsulant 320 and may electrically connect the lower redistribution layer 312 and the upper redistribution layer 352. The plurality of posts 330 may horizontally overlap the lower chip structure 100. For example, upper surfaces of the plurality of posts 330 may be at a higher vertical level than an upper surface of the lower chip structure 100, and lower surfaces of the plurality of posts 330 may be at a lower vertical level than a lower surface of the lower chip structure 100. The plurality of posts 330 may include copper (Cu), nickel (Ni), titanium (Ti), lead (Pb), aluminum (Al), silver (Ag), gold (Au), platinum (Pt), or alloys thereof. Each of the plurality of posts 330 may extend in the vertical direction D3 in the encapsulant 320. The plurality of posts 330 may have a cylindrical shape, but an example embodiment thereof is not limited thereto.

Each of the plurality of posts 330 may include a lower metal layer 331 adjacent to the lower redistribution structure 310 and an upper metal layer 332 adjacent to the upper redistribution structure 350. In an example embodiment, the lower metal layer 331 may be referred to as a first portion, and the upper metal layer 332 may be referred to as a second portion.

The lower metal layer 331 may be disposed on the lower redistribution layer 312 of the lower redistribution structure 310 and may extend from an upper surface of the lower redistribution layer 312 in the vertical direction D3. For example, a lower surface of the lower metal layer 331 may contact an upper surface of an uppermost one of the lower redistribution layer 312 of the lower redistribution structure 310. Widths of the lower metal layer 331 in the horizontal directions (horizontal directions D1 and/or D2) depending on a height H_L taken in the vertical direction D3 may be substantially the same. For example, a width in the horizontal directions (horizontal directions D1 and/or D2) of the lower metal layer 331 may be constant along the lower metal layer 331. An upper surface of the lower metal layer 331 may be at a level higher than a level of an upper surface of the lower chip structure 100 with respect to an upper surface of the lower redistribution structure 310.

The upper metal layer 332 may be disposed between the lower metal layer 331 and the upper redistribution structure 350. The upper metal layer 332 may be disposed on the lower metal layer 331. For example, a lower surface of the upper metal layer 332 may contact an upper surface of the lower metal layer 331. The upper metal layer 332 may be disposed between, for example, the lower metal layer 331 and a lowermost upper redistribution via 353L among the upper redistribution vias 353. Widths in the horizontal direction (D1 and/or D2) of the upper metal layer 332 may vary depending on the height H_U taken in the vertical direction D3. The width W1 of a lower region of the upper metal layer 332 may be smaller than the width W2 of the upper region of the upper metal layer 332. For example, the width W1 of the lower surface of the upper metal layer 332 may be smaller than the width W2 of the upper surface of the upper metal layer 332. The width of the upper metal layer 332 may, for example, increase from the lower region of the upper metal layer 332 to the upper region of the upper metal layer 332. A minimum value of the width W1 of the lower region of the upper metal layer 332 may be defined on the lower surface of the upper metal layer 332, and a maximum value of the width W2 of the upper region of the upper metal layer 332 may be defined on the upper surface of the upper metal layer 332. In example embodiments, a side surface of the upper metal layer 332 may have a continuous slope. For example, the upper metal layer 332 may have a tapered shape.

A ratio of the width of the upper surface of the upper metal layer 332 (e.g., width W2) to the width of the lower surface of the upper metal layer 332 (e.g., width W1) may be about 1.5 or more. In an example embodiment, the ratio may be in the range of about 1.5 or more to about 3.0 or less. In an example embodiment, the ratio may be in the range of about 1.5 or more to about 2.0 or less.

An angle θ formed by the upper surface of the upper metal layer 332 and the side surface of the upper metal layer 332 may be in the range of about 20° to about 80°. In an example embodiment, the angle θ may be in the range of about 30° to about 70°. In an example embodiment, the angle θ may be in the range of about 30° to about 60°.

Surface roughness of the side surface of the upper metal layer 332 may be greater than surface roughness of the side surface of the lower metal layer 331. In another aspect, a plurality of grooves GR may be formed in the side surface of the upper metal layer 332. Here, the plurality of grooves GR may refer to a recessed portion of an unevenness formed on the side surface of the upper metal layer 332. The surface roughness may be measured using a contact or non-contact surface roughness meter. Contact methods may include, for example, a stylus surface roughness meter, and non-contact methods may include, for example, an atomic force microscope, a laser microscope, etc.

The first height H_L in the vertical direction D3 of the lower metal layer 331 may be greater than a second height H_U in the vertical direction D3 of the upper metal layer 332. For example, the ratio of the first height H_L to the second height H_U may be about 1.5 or more. In an example embodiment, the ratio may be in the range of about 1.5 to about 10.0. In an example embodiment, the ratio may be in the range of about 2.0 to about 8.0. In an example embodiment, the ratio may be in the range of about 2.0 to about 5.0.

A width of the lower surface of the upper metal layer 332 may be less than a width of the upper surface of the lower metal layer 331. In another aspect, an edge of the upper surface of the lower metal layer 331 may be covered by the encapsulant 320. For example, the encapsulant 320 may contact a portion of the upper surface of the lower metal layer 331.

A width of the lower surface of the lowermost upper redistribution via 353L may be less than a width of the upper surface of the upper metal layer 332. In another aspect, an edge of the upper surface of the upper metal layer 332 may be covered by the upper insulating layer 351 of the upper redistribution structure 350. For example, the upper insulating layer 351 may contact a portion of the upper surface of the upper metal layer 332.

The encapsulant 320 may cover the lower chip structure 100 and a side surface of each of a plurality of posts 330. For example, the encapsulant 320 may contact the lower chip structure 100 and a side surface of each of a plurality of posts 330. The encapsulant 320 may be formed of or include, for example, a thermosetting resin such as an epoxy resin, a thermoplastic resin such as a polyimide, or a prepreg, ABF, FR-4, BT, epoxy molding compound (EMC), or the like.

The encapsulant 320 may be defined to include a plurality of first to third portions 320_1, 320_2, and 320_3. A boundary between the plurality of first to third portions 320_1, 320_2, and 320_3 may not be distinct.

The first portion 320_1 may be a portion of the encapsulant 320 covering an upper portion (or upper surface) of the lower chip structure 100. For example, the first portion 320_1 may contact the upper surface of the lower chip structure 100.

The second portion 320_2 may extend from the first portion 320_1 in the horizontal direction (D1 and/or D2) and may surround an upper end of the lower metal layer 331 and a side surface of the upper metal layer 332. The second portion 320_2 may, for example, cover an edge of the upper surface of the lower metal layer 331 and may surround a side surface of an upper end of the lower metal layer 331. The second portion 320_2 may, for example, surround a side surface of the upper metal layer 332. For example, the second portion 320_2 may contact side surfaces of the upper metal layers 332, portions of the upper surfaces of the lower metal layers 331, and portions of the side surfaces of the lower metal layers 331. The second portion 320_2 may, for example, fill the plurality of grooves GR of an unevenness formed on the side surface of the upper metal layer 332.

The third portion 320_3 may extend downwardly from the second portion 320_2, may cover a side portion and a lower surface of the lower chip structure 100, and may surround a portion other than the upper end of the lower metal layer 331. For example, the third portion 320_3 may contact the side surface of the lower chip structure 100, side surfaces of the lower metal layers 331, portions of the upper surfaces of the uppermost ones of the lower redistribution layers 312, and side surfaces of the uppermost ones of the lower redistribution layers 312.

The upper redistribution structure 350 may be disposed on the encapsulant 320, and may include an upper insulating layer 351, upper redistribution layers 352, and upper redistribution vias 353.

The upper insulating layer 351 may be formed of or include a thermosetting resin such as an epoxy resin, a thermoplastic resin such as a polyimide, or a resin impregnated with an inorganic filler, for example, prepreg, ABF, FR-4, or BT. For example, the upper insulating layer 351 may include a photosensitive resin such as PID. The upper insulating layer 351 may include a plurality of insulating layers stacked in the vertical direction D3. Depending on processes, a boundary between the plurality of insulating layers may not be distinct. The upper insulating layer 351 may cover an edge of the upper surface of the upper metal layer 332.

The upper redistribution layers 352 may be disposed on and in the upper insulating layer 351. The upper redistribution layers 352 may redistribute a chip structure mounted on the upper redistribution structure 350, for example, an upper chip structure 200 in FIG. 7. The upper redistribution layers 352 may be formed of or include a metal including, for example, copper (Cu), aluminum (Al), silver (Ag), tin (Sn), gold (Au), nickel (Ni), lead (Pb), titanium (Ti), or an alloy thereof. The upper redistribution layers 352 may include a ground pattern, a power pattern, and a signal pattern depending on a design. The upper redistribution layer 352 may include more or fewer redistribution layers than the example illustrated in the diagram.

The upper redistribution vias 353 may extend in the upper insulating layer 351 and may be electrically connected to the upper redistribution layers 352. For example, the upper redistribution vias 353 may interconnect the upper redistribution layers 352 disposed on different levels. The upper redistribution vias 353 may be formed of or include a metal material, for example, copper (Cu), aluminum (Al), silver (Ag), tin (Sn), gold (Au), nickel (Ni), lead (Pb), titanium (Ti), or an alloy thereof. Each of the upper redistribution vias 353 may be a filled via in which the metal material is filled in the via-hole, or a conformal via in which the metal material extends along an inner wall of the via-hole.

A via positioned in a lowermost end of the upper redistribution via 353 may be defined as a lowermost upper redistribution via 353L. A lower end of the lowermost upper redistribution via 353L may be in contact with an upper end of the upper metal layer 332.

A width of a lower surface of the lowermost upper redistribution via 353L may be smaller than a width of the upper surface of the upper metal layer 332. For example, the width of the lower surface of the lowermost upper redistribution via 353L may be smaller than the width W2 of the upper surface of the upper metal layer 332.

In example embodiments, a post 330 may have a lower metal layer 331 and an upper metal layer 332 disposed on the lower metal layer 331 and having a width different from that of the lower metal layer 331, such that delamination occurring on an interfacial surface between the post 330 and the encapsulant 320 may be reduced or prevented. Also, surface roughness of the side surface of the upper metal layer 332 may be greater than surface roughness of the side surface of the lower metal layer 331, such that delamination may be reduced or prevented.

For example, a width of the lower surface of the upper metal layer 332 may be smaller than a width of the upper surface of the lower metal layer 331, and a width of the upper metal layer 332 may increase toward an upper region of the upper metal layer 332, and accordingly, adhesive force on an interfacial surface between an upper end of the post 330 and the encapsulant 320 may be improved. Since surface roughness of the side surface of the upper metal layer 332 may be greater than surface roughness of the side surface of the lower metal layer 331, an adhesive force may be improved.

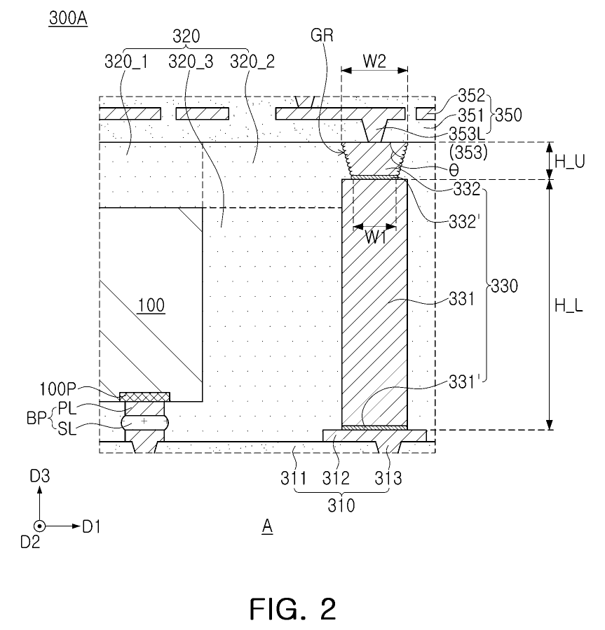

FIG. 2 is a diagram illustrating a modified example in an example embodiment.

Referring to FIG. 2, a semiconductor package 300A may be substantially the same as the example described with reference to FIGS. 1A to 1C, other than the configuration in which a seed layer (e.g., seed layer 331’ and seed layer 332’) disposed in a lower portion of the metal layer (e.g., lower metal layer 331 and upper metal layer 332) is further included.

A lower seed layer 331’ may be disposed in a lower portion of the lower metal layer 331. The lower seed layer 331’ may contact an upper surface of an uppermost one of the lower redistribution layers 312. The lower seed layer 331’ may include titanium (Ti), copper (Cu), or the like.

An upper seed layer 332’ may be disposed in a lower portion of the upper metal layer 332. The upper seed layer 332’ may contact an upper surface of the lower metal layer 331. The upper seed layer 332’ may include titanium (Ti), copper (Cu), or the like.

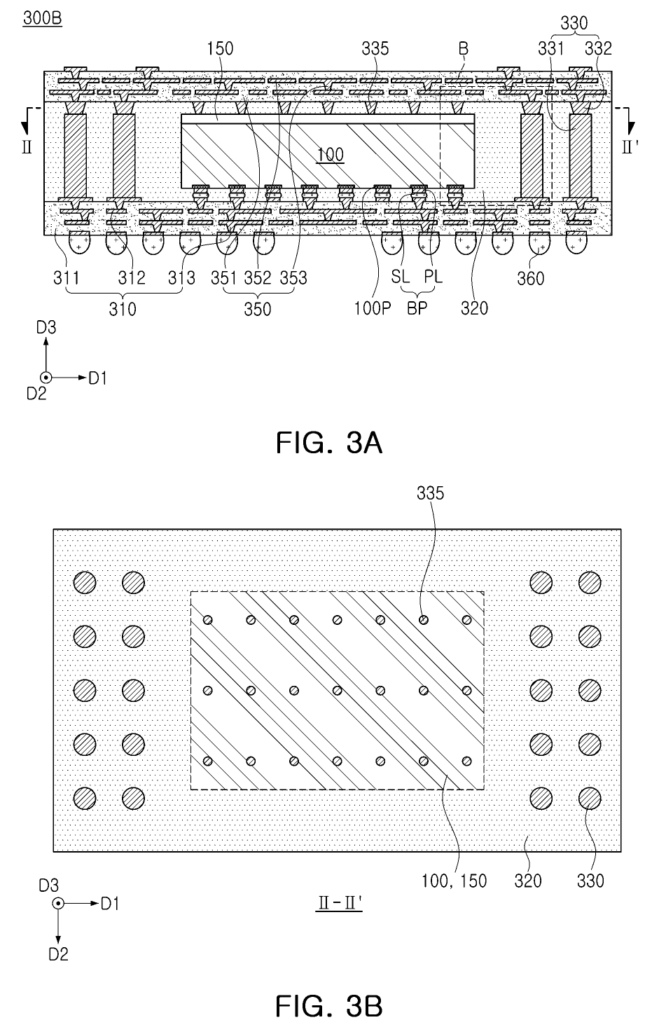

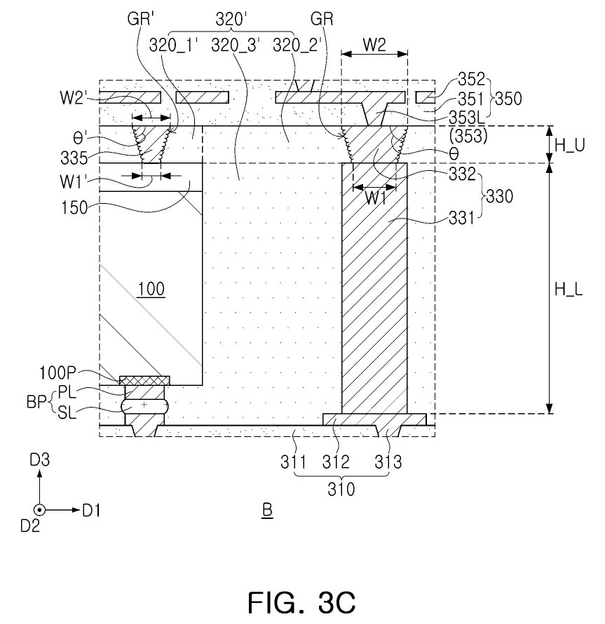

FIG. 3A is a cross-sectional diagram illustrating a semiconductor package according to an example embodiment. FIG. 3B is a plan diagram taken along line I-I’ in FIG. 3A. FIG. 3C is an enlarged diagram illustrating region ‘B’ in FIG. 3A.

Referring to FIGS. 3A to 3C, a semiconductor package 300B may be substantially the same as the example described with reference to FIGS. 1A to 2, other than the configuration in which a cover layer 150 and a plurality of via structures 335 on the upper surface of the lower chip structure 100 is further included.

The cover layer 150 may be disposed on the lower chip structure 100. The cover layer 150 may be formed by a deposition process such as PVD, CVD, or a spin coating process. The cover layer 150 may include silicon oxide (SiO), silicon nitride (SiN), silicon carbonitride (SiCN), and combinations thereof.

A side surface of the cover layer 150 and a side surface of the lower chip structure 100 may be aligned. The cover layer 150 may include a first surface in contact with an upper surface of the lower chip structure 100 and a second surface opposite the first surface.

A plurality of via structures 335 may penetrate the encapsulant 320 between the cover layer 150 and the upper redistribution structure 350. The plurality of via structures 335 may be spaced apart from each other in the first horizontal direction D1 and the second horizontal direction D2. Each of the plurality of via structures 335 may be a dummy via structure not forming an electrical connection. In another aspect, a redistribution via may not be disposed on the plurality of via structures 335. The plurality of via structures 335 may include the same material as the upper metal layer 332. For example, the plurality of via structures 335 may include copper (Cu), nickel (Ni), titanium (Ti), lead (Pb), aluminum (Al), silver (Ag), gold (Au), platinum (Pt), or alloys thereof.

A width in each of the horizontal directions (D1 and/or D2) of the plurality of via structures 335 may vary with respect to a height in the vertical direction D3. A width W1’ of a lower region of the via structure 335 may be less than a width W2’ of an upper region of the via structure 335. For example, the width W1’ of a lower surface of the via structure 335 may be less than the width W2’ of an upper surface of the via structure 335. The width of the via structure 335 may increase, for example, from the lower region of the via structure 335 to the upper region of the via structure 335. A minimum value of the width W1’ of a lower region of the via structure 335 may be defined at the lower surface of the via structure 335, and a maximum value of the width W2’ of the upper region of the via structure 335 may be defined at the upper surface of the via structure 335.

A ratio of the width of the upper surface of the via structure 335 (e.g., width W2’) to the width of the lower surface of the via structure 335 (e.g., width W1’) may be about 1.5 or more. In an example embodiment, the ratio may be in the range of about 1.5 or more to about 3.0 or less. In an example embodiment, the ratio may be in the range of about 1.5 or more to about 2.0 or less. The ratio of the width of the upper surface of the via structure 335 (e.g., width W2’) to the width of the lower surface of the via structure 335 (e.g., width W1’) may be less than the ratio of the width of the upper surface of the upper metal layer 332 (e.g., width W2) to the width of the lower surface of the upper metal layer 332 (e.g., width W1).

The width of the via structure 335 may be less than the width of the upper metal layer 332 in the horizontal direction (D1 and/or D2). The width of the lower surface of the via structure 335 (e.g., width W1’) may be less than the width of the lower surface of the upper metal layer 332 (e.g., width W1). The width of the upper surface of the via structure 335 (e.g., width W2’) may be smaller than the width of the upper surface of the upper metal layer 332 (e.g., width W2).

A height in the vertical direction D3 of the via structure 335 may be substantially the same as a height H_U in the vertical direction D3 of the upper metal layer 332.

An angle θ’ formed by the upper surface of the via structure 335 and the side surface of the via structure 335 may be in the range of about 20° to about 80°. In an example embodiment, the angle θ’ may be in the range of about 30° to about 70°. In an example embodiment, the angle θ’ may be in the range of about 30° to about 60°. The angle θ’ formed by the upper surface of the via structure 335 and the side surface of the via structure 335 may be greater than the angle θ formed by the upper surface of the upper metal layer 332 and the side surface of the upper metal layer 332.

The side surface of the via structure 335 may have surface roughness. In another aspect, a plurality of grooves GR’ may be formed on the side surface of the via structure 335. Here, the plurality of grooves GR’ may refer to a recessed portion of an unevenness formed on the side surface of the via structure 335.

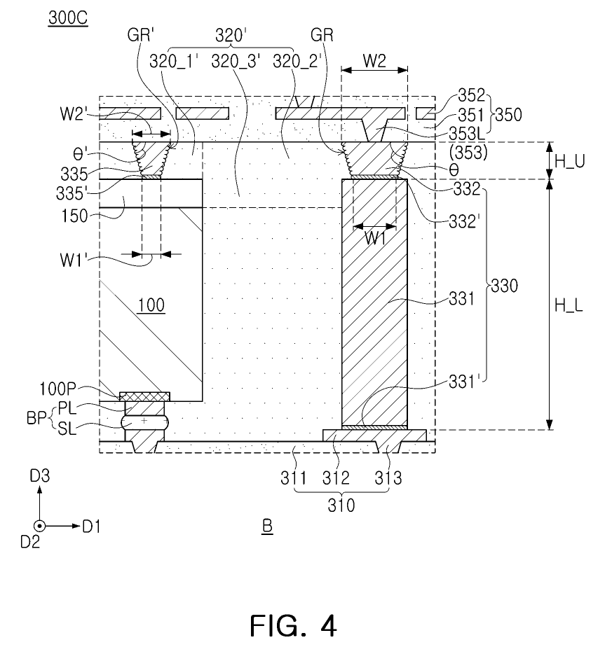

FIG. 4 is a diagram illustrating a modified example according to an example embodiment.

Referring to FIG. 4, a semiconductor package 300C may be substantially the same as the example described with reference to FIGS. 1A to 3C, other than in which a seed layer (e.g., seed layer 331’ and seed layer 332’) disposed in a lower portion of a metal layer (e.g., lower metal layer 331 and upper metal layer 332) and a seed layer 335’ disposed in a lower portion of a via structure 335 are further included.

A lower seed layer 331’ may be disposed in a lower portion of a lower metal layer 331. The lower seed layer 331’ may contact an upper surface of an uppermost one of the lower redistribution layers 312. The lower seed layer 331’ may include titanium (Ti), copper (Cu), or the like.

An upper seed layer 332’ may be disposed in a lower portion of an upper metal layer 332. The upper seed layer 332’ may contact an upper surface of the lower metal layer 331 The upper seed layer 332’ may include titanium (Ti), copper (Cu), or the like.

A seed layer 335’ may be disposed in a lower portion of the via structure 335. The seed layer 335’ may contact an upper surface of the cover layer 150. The seed layer 335’ may include titanium (Ti), copper (Cu), or the like.

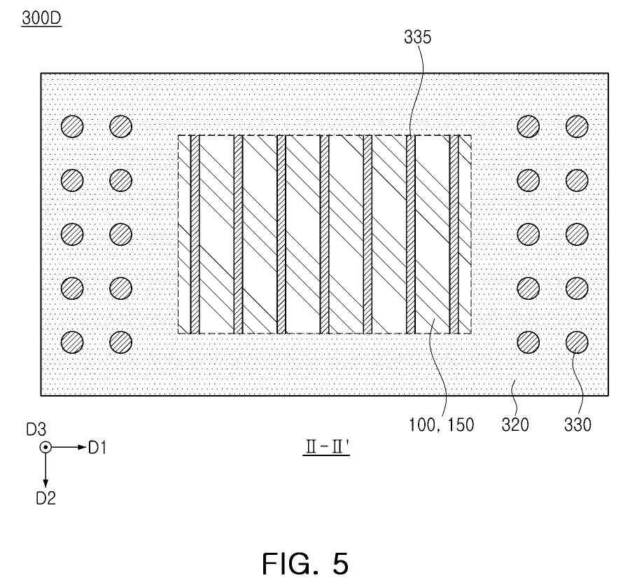

FIG. 5 is a cross-sectional diagram illustrating a semiconductor package according to an example embodiment.

Referring to FIG. 5, a semiconductor package 300D may be substantially the same as the example described with reference to FIGS. 1A to 4, other than the configuration in which a plurality of via structures 335 spaced apart from each other in a first direction (e.g., D1) and each extending in a second direction (e.g., D2).

A plurality of via structures 335 may be spaced apart from each other in a first horizontal direction D1. Each of the plurality of via structures 335 may extend lengthwise in a second horizontal direction D2. In another aspect, the plurality of via structures 335 may be spaced apart from each other in the second horizontal direction D2, and each of the plurality of via structures 335 may extend lengthwise in the first horizontal direction D1.

FIG. 6 is a cross-sectional diagram illustrating a semiconductor package according to an example embodiment.

Referring to FIG. 6, a semiconductor package 300E may be configured substantially the same as the example described with reference to FIGS. 1A to 5, other than the configuration in which a lower chip structure (or ‘chip structure’) in which a plurality of semiconductor chips 100a and 100b are embedded is included.

At least a portion of the plurality of semiconductor chips 100a and 100b (e.g., semiconductor chip 100a) may include through-vias 130 electrically interconnecting the plurality of semiconductor chips 100a and 100b. The plurality of semiconductor chips 100a and 100b may be chiplets included in a multi-chip module (MCM). The plurality of semiconductor chips 100a and 100b may include a central processor (CPU), a graphics processor (GPU), a filled programmable gate array (FPGA), a digital signal processor (DSP), an encryption processor, a microprocessor, a microcontroller, an analog-to-digital converter, an application-specific integrated circuit (ASIC), a volatile memory, a non-volatile memory, an input/output (I/O) circuit, an analog circuit, a serial-to-parallel conversion circuit, or the like.

The chip structure may include a base chip 100a and at least one stack chip 100b. For example, the base chip 100a may include a processor circuit, and at least one stack chip 100b may include at least one of an input/output circuit, an analog circuit, a memory circuit, and a serial-to-parallel conversion circuit for the processor circuit. The number of the base chip 100a and at least one stack chip 100b may be greater number than the example illustrated in the diagram. For example, the at least one stack chip 100b may include two or more semiconductor chips arranged horizontally and/or vertically on the base chip 100a.

The base chip 100a and at least one stack chip 100b may include a substrate 101, an upper protective layer 103, an upper pad 105, a circuit layer 110, lower pads 104, and/or through-vias 130. The substrate 101 may include a semiconductor element, such as silicon or germanium (Ge), for example, or a compound semiconductor, such as silicon carbide (SiC), gallium arsenide (GaAs), indium arsenide (InAs), or indium phosphide (InP). The substrate 101 may have a silicon on insulator (SOI) structure. The substrate 101 may have a conductive region, such as a well doped with impurities, or an active surface and an opposite passive surface doped with impurities. The substrate 101 may include various device isolation structures, such as a shallow trench isolation (STI) structure.

The upper protective layer 103 may be formed on an inactive surface of the substrate 101 and may protect the substrate 101. The upper protective layer 103 may be formed of an insulating layer such as a silicon oxide film, a silicon nitride film, a silicon oxynitride film, or the like, but the material of the upper protective layer 103 is not limited to the materials. For example, the upper protective layer 103 may be formed of a polymer such as PI (polyimide). Although not illustrated in the diagram, a lower protective layer may be further formed on a lower surface of the circuit layer 110.

The upper pad 105 may be disposed on the upper protective layer 103. The upper pad 105 may include, for example, at least one of aluminum (Al), copper (Cu), nickel (Ni), tungsten (W), platinum (Pt), and gold (Au). The lower pads 104 may be disposed on a lower portion of the circuit layer 110 and may include a material similar to that of the upper pad 105. However, the material of the upper pads 105 and the lower pads 104 is not limited to the above materials. The lower pads 104 may be understood to correspond to the first connection terminals 100P described above.

The circuit layer 110 may be disposed on an active surface of the substrate 101 and may include various types of elements. For example, the circuit layer 110 may include various active elements and/or passive elements, such as a planar field effect transistor (FET) or FinFET, memory elements such as flash memory, dynamic random access memory (DRAM), static random access memory (SRAM), electrically erasable programmable read-only memory (EEPROM), phase-change random access memory (PRAM), magnetoresistive random access memory (MRAM), ferroelectric random access memory (FeRAM), and resistive random access memory (RRAM), logic elements AND, OR, and NOT, and various active elements and/or passive elements such as system large scale integration (LSI), CMOS imaging sensor (CIS), and micro-electro-mechanical system (MEMS). The circuit layer 110 may include an interconnection structure electrically connected to the above-described elements and an interlayer insulating layer surrounding the interconnection structure. The interlayer insulating layer may include silicon oxide or silicon nitride. The interconnection structure may include a multilayer interconnection and/or vertical contact. The interconnection structure may connect elements of the circuit layer 110 to each other, may connect elements to conductive regions of the substrate 101, or may connect elements to the through-vias 130.

The through-vias 130 may penetrate the substrate 101 in the vertical direction (D3 direction) and may provide an electrical path connecting the upper pads 105 to the lower pads 104. The through-via 130 may include a conductive plug and a barrier film surrounding the conductive plug. The conductive plug may include a metal, for example, tungsten (W), titanium (Ti), aluminum (Al), or copper (Cu). The conductive plug may be formed by a plating process, a PVD process, or a CVD process. The barrier film may include an insulating barrier film and/or a conductive barrier film. The insulating barrier film may be formed of an oxide film, a nitride film, a carbide film, a polymer, or a combination thereof. A conductive barrier film may be disposed between the insulating barrier film and the conductive plug. The conductive barrier film may include a metal compound such as, for example, tungsten nitride (WN), titanium nitride (TiN), or tantalum nitride (TaN). The barrier film may be formed by a PVD process or a CVD process.

Bumps 141 and an adhesive layer 142 may be disposed between the base chip 100a and at least one stack chip 100b. The bumps 141 may electrically connect the base chip 100a to at least one stack chip 100b. The bumps 141 may include tin (Sn), indium (In), bismuth (Bi), antimony (Sb), copper (Cu), silver (Ag), zinc (Zn), lead (Pb), and/or alloys thereof, and a metal pillar and a solder ball may be combined in the bumps 141. The adhesive layer 142 may surround each of the bumps 141 and may bond the base chip 100a to at least one stack chip 100b. The adhesive layer 142 may be formed using a non-conductive film (NCF), but an example embodiment thereof is not limited thereto, and the adhesive layer 142 may be formed by any kind of insulating film on which thermocompression bonding process is able to be performed, for example. In example embodiments, the adhesive layer 142 may cover at least a portion of a side surface of at least one stack chip 100b.

At least one stack chip 100b and a mold 143 surrounding an external side surface of the adhesive layer 142 may be disposed on the base chip 100a. The mold 143 may include a thermosetting resin such as an epoxy resin, a thermoplastic resin such as a polyimide, or a prepreg, ABF, FR-4, BT, EMC, or the like.

FIG. 7 is a cross-sectional diagram illustrating a semiconductor package according to an example embodiment.

Referring to FIG. 7, a semiconductor package 300F may be configured substantially the same as the example described with reference to FIGS. 1A to 6, other than the configuration in which a lower chip structure (or ‘chip structure’) in which a base chip 100a and stack chips 100b are directly bonded and coupled to each other is included.

The chip structure may include a base chip 100a, at least one stack chip 100b, and a mold 143. The base chip 100a and the at least one stack chip 100b may be directly bonded and coupled to each other without a connecting member (e.g., solder bump, copper pillar, or the like). The chip structure may include a bonding surface BS in which an upper surface of the base chip 100a and a lower surface of at least one stack chip 100b are bonded to each other. The bonding surface BS may be formed by metal bonding and dielectric bonding. The upper pads 105 of the base chip 100a and the lower pads 104 of the stack chip 100b may include copper (Cu). The upper protective layer 103 surrounding the upper pads 105 of the base chip 100a and the dielectric layer surrounding the lower pads 104 of the stack chip 100b may include at least one of materials bonded and coupled to each other, for example, silicon oxide (SiO), silicon nitride (SiN), and silicon carbonitride (SiCN).

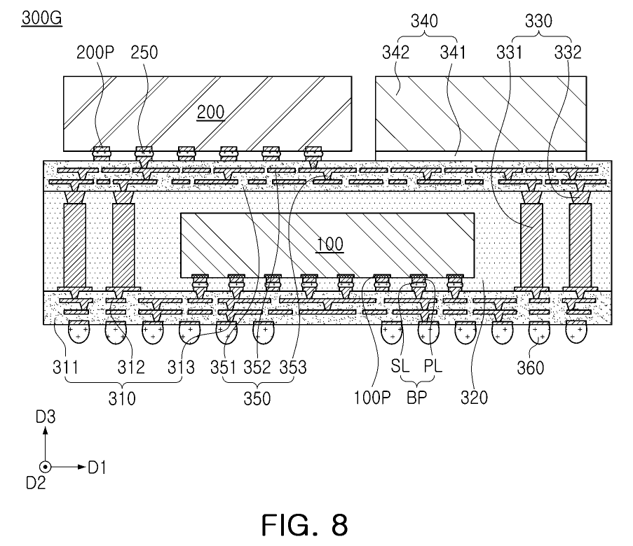

FIG. 8 is a cross-sectional diagram illustrating a semiconductor package according to an example embodiment.

Referring to FIG. 8, a semiconductor package 300G may be configured substantially the same as the example described with reference to FIGS. 1A to 7, other than the configuration in which the upper chip structure 200 and/or the heat dissipation member 340 are included.

The upper chip structure 200 may be a bare chip or a packaged chip having a logic circuit or a memory circuit formed thereon. In example embodiments, the upper chip structure 200 may be a package structure having a plurality of semiconductor chips mounted on a substrate. The upper chip structure 200 may include a different type of semiconductor chip from the lower chip structure 100. For example, the lower chip structure 100 may include a logic chip, and the upper chip structure 200 may include a memory chip.

The upper chip structure 200 may be disposed on the upper redistribution structure 350. The upper chip structure 200 may be electrically connected to the lower redistribution layer 312 through a plurality of posts 330. In example embodiments, the plurality of posts 330 may be arranged in positions overlapping the upper chip structure 200 in the vertical direction D3. The upper chip structure 200 may include second connection terminals 200P electrically connected to the plurality of posts 330. The second connection terminals 200P may be connected to the plurality of posts 330 through upper connection bumps 250 disposed between the upper chip structure 200 and the plurality of posts 330. The upper chip structure 200 may be electrically connected to the lower chip structure 100 through the lower redistribution layer 312 and the plurality of posts 330. In example embodiments, an insulating material layer may be formed below the upper chip structure 200 surrounding the upper connection bumps 250.

The heat dissipation member 340 may be disposed on at least one side of the upper chip structure 200. The heat dissipation member 340 may overlap at least a portion of the lower chip structure 100 in the vertical direction (in the D3 direction). In example embodiments, the heat dissipation member 340 may have a shape surrounding four sides of the upper chip structure 200. The heat dissipation member 340 may control warpage of the semiconductor package 300G and may dissipate heat generated from the lower chip structure 100 externally.

The heat dissipation member 340 may include a thermally conductive material layer (thermal interface material, TIM) 341, and a heat slug 342. The thermally conductive material layer 341 may be in contact with an upper surface 100T of the lower chip structure 100. The thermally conductive material layer 341 may be formed of or include, for example, a thermally conductive adhesive tape, a thermally conductive grease, a thermally conductive adhesive, or the like. The heat slug 342 may be disposed on the thermally conductive material layer 341. The heat slug 342 may be formed of or include a material having excellent thermal conductivity, for example, aluminum (Al), gold (Au), silver (Ag), copper (Cu), iron (Fe), graphite, graphene, or the like.

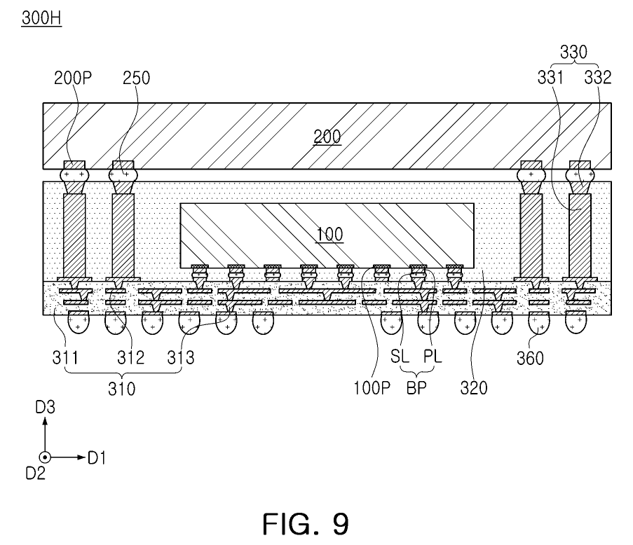

FIG. 9 is a cross-sectional diagram illustrating a semiconductor package according to an example embodiment.

Referring to FIG. 9, a semiconductor package 300H may be configured substantially the same as the example described with reference to FIGS. 1A to 8, other than the configuration in which another upper redistribution structure (e.g., 350 in FIG. 1A) is not included in and the upper chip structure 200 is disposed on the encapsulant 320.

The upper chip structure 200 may be a bare chip or a packaged chip in which a logic circuit or a memory circuit is formed. In example embodiments, the upper chip structure 200 may be a package structure in which a plurality of semiconductor chips are mounted on a substrate. The upper chip structure 200 may include a different type of semiconductor chip from the lower chip structure 100. For example, the lower chip structure 100 may include a logic chip, and the upper chip structure 200 may include a memory chip.

The upper chip structure 200 may be disposed on the encapsulant 320. The upper chip structure 200 may include a lower surface on which the second connection terminal 200P is disposed. At least a portion of the lower surface of the second connection terminal 200P and at least a portion of the upper surface of the upper metal layers 332 of the post 330 may oppose each other. In another aspect, the second connection terminal 200P and the upper metal layers 332 may be aligned in the vertical direction (e.g., D3 direction).

The semiconductor package 300H may further include connection bumps 250 between the upper chip structure 200 and the encapsulant 320. The connection bumps 250 may be disposed between the second connection terminals 200P and the upper metal layers 332. For example, each connection bump 250 may contact a lower surface of a corresponding one of the second connection terminals 200P and an upper surface of a corresponding one of the upper metal layers 332. The connection bumps 250 may electrically connect the second connection terminals 200P to the upper metal layers 332. The upper chip structure 200 may be electrically connected to the lower redistribution layer 312 through the connection bumps 250 and posts 330. In example embodiments, an insulating material layer may be formed below the upper chip structure 200 surrounding the connection bumps 250.

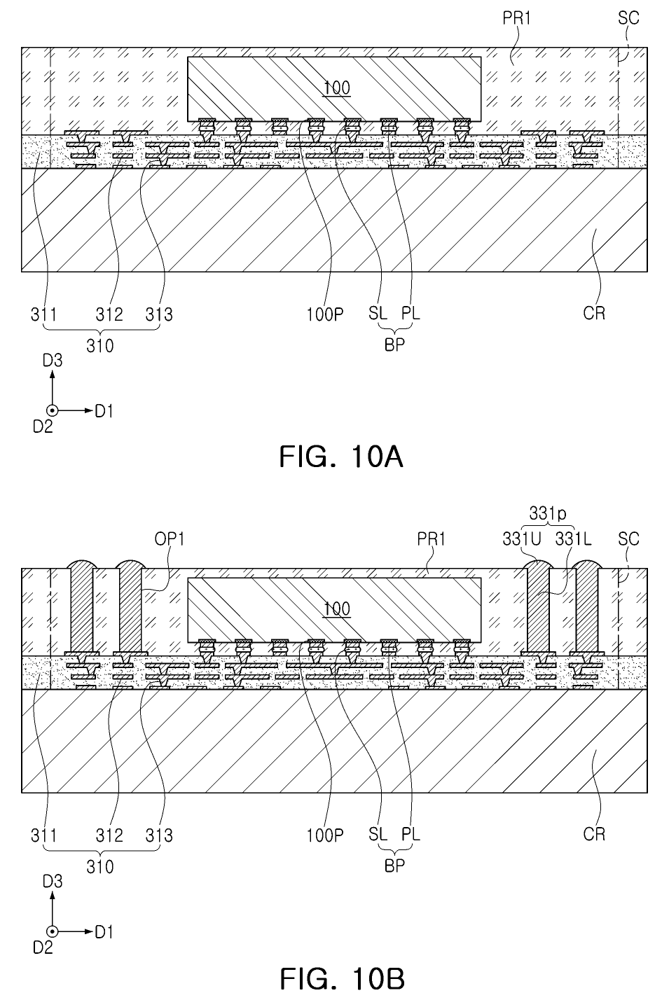

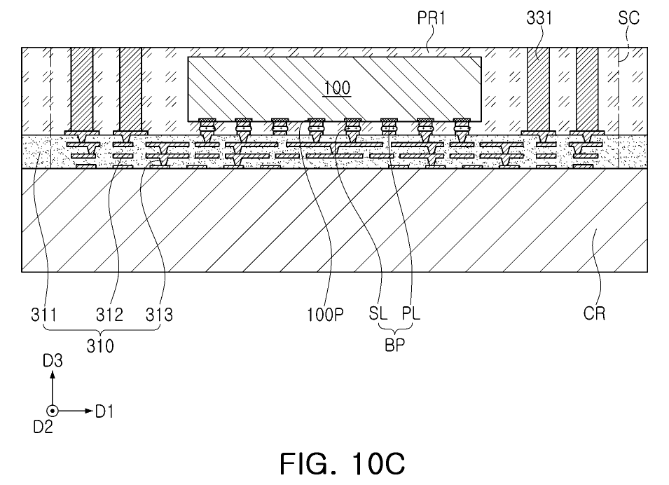

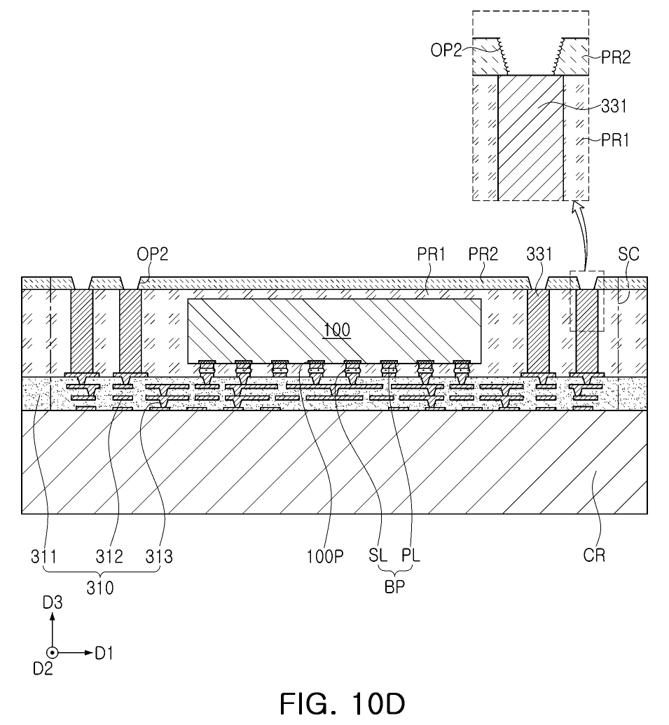

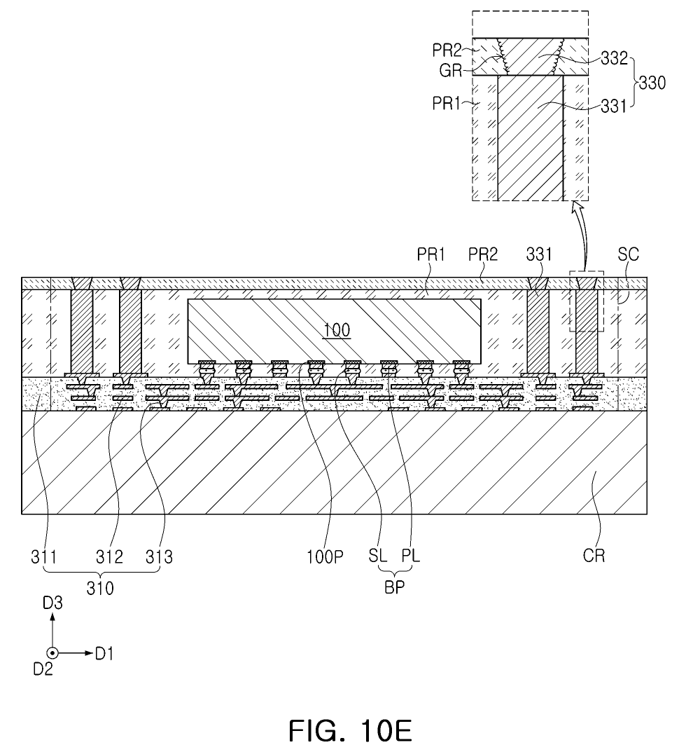

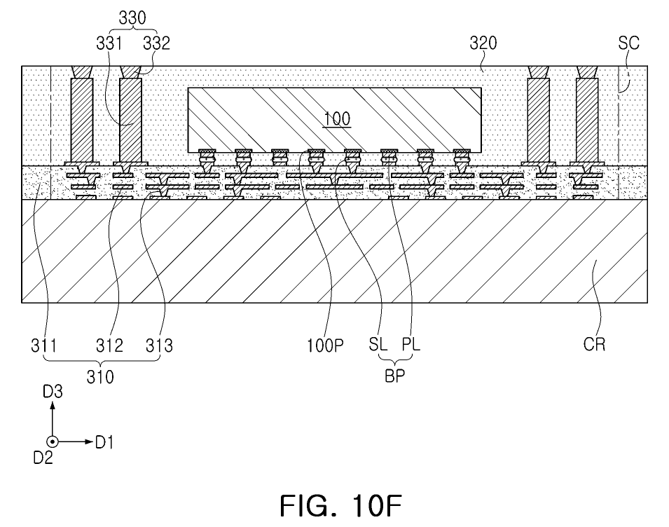

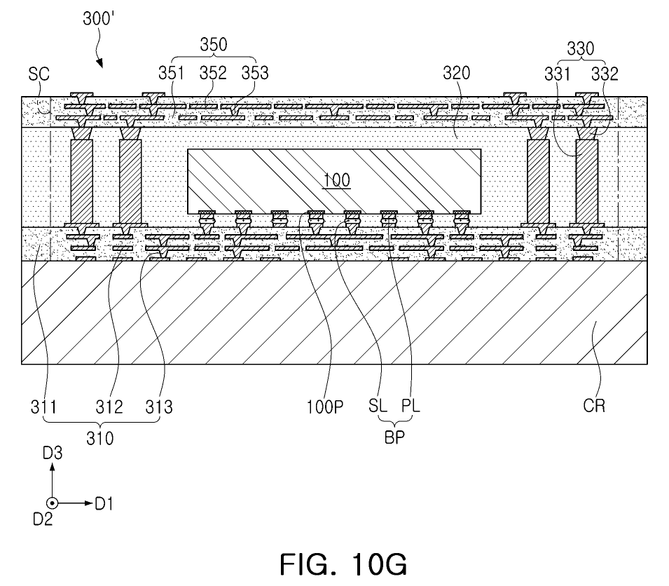

FIGS. 10A to 10G are cross-sectional diagrams illustrating processes of manufacturing a semiconductor package according to an example embodiment.

Referring to FIG. 10A, a chip structure 100 may be mounted on a lower redistribution structure 310. For example, the chip structure 100 may be mounted between scribe lines SC. The lower redistribution structure 310 may be formed on a carrier substrate CR. A first photoresist layer PR1 may be formed on the lower redistribution structure 310 and the chip structure 100.

The lower redistribution structure 310 may be formed at a wafer level or a panel level. The lower redistribution structure 310 may include a lower insulating layer 311, a lower redistribution layer 312, and a lower redistribution via 313. The lower insulating layer 311 may be formed by sequentially applying and curing a photosensitive material, for example, PID. The lower redistribution layer 312 and the lower redistribution via 313 may be formed by forming a via-hole penetrating the lower insulating layer 311 by performing an exposure process and a development process, and patterning a metal material on the lower insulating layer 311 using a plating process.

The chip structure 100 may be formed on the lower redistribution structure 310. The first connection terminals 100P and the lower redistribution layer 312 may be physically and electrically connected to each other through connection bumps BP disposed between the chip structure 100 and the lower redistribution structure 310.

A first photoresist layer PR1 may be formed to cover the chip structure 100 on the lower redistribution structure 310. The first photoresist layer PR1 may be formed through a spin coating process or other suitable coating method. The first photoresist layer PR1 may work as a mask for forming a portion of the post (e.g., posts 330 in FIG. 1A). In an example embodiment, the first photoresist layer PR1 may include a positive or negative photoresist. In an example embodiment, the first photoresist layer PR1 may include a negative photoresist.

Referring to FIG. 10B, a plurality of preliminary lower metal layers 331p may be formed.

A plurality of first openings OP1 penetrating the first photoresist layer PR1 and exposing the upper surface of the lower redistribution layer 312 may be formed. The plurality of first openings OP1 may be formed by a first exposure process and a first development process.

The plurality of first openings OP1 may be filled with a conductive material, such that a lower portion 331L filling the plurality of first openings OP1 and an upper portion 331U on the first photoresist layer PR1 may be formed.

The preliminary lower metal layer 331p may be formed by an electroplating process using a seed layer (see, e.g., seed layer 331’ in FIG. 2) in the plurality of first openings OP1. The seed layer may include titanium (Ti), copper (Cu), or the like.

Referring to FIG. 10C, a plurality of lower metal layers 331 may be formed.

Referring to FIGS. 10B and 10C together, a planarization process may be applied to remove the upper portion 331U and to allow the upper surface of the first photoresist layer PR1 to be substantially coplanar. The planarization process may include a grinding process, a chemical mechanical polishing (CMP) process, or the like, but an example embodiment thereof is not limited thereto.

Planarizing the upper surface of the first photoresist layer PR1 may include generating a standing wave in the second exposure process to form a second opening (e.g., second opening OP2 in FIG. 10D) penetrating the second photoresist layer (e.g., second photoresist layer PR2 in FIG. 10D). For example, planarizing the upper surface of the first photoresist layer PR1 may be utilized for generating a standing wave.

Referring to FIG. 10D, a second photoresist layer PR2 may be formed on the first photoresist layer PR1 and a plurality of lower metal layers 331.

A plurality of second openings OP2 penetrating the second photoresist layer PR2 and exposing the upper surface of the lower metal layer 331 may be formed. The plurality of second openings OP2 may be formed by a second exposure process and a second development process.

A width of a lower surface of each of the plurality of second openings OP2 may be smaller than a width of an upper surface of the lower metal layer 331. Each of the plurality of second openings OP2 may have a width increasing from the lower region to the upper region. For example, the plurality of second openings OP2 may have an inverted trapezoidal shape in terms of cross-sectional area.

A plurality of grooves may be formed on an internal side wall of each of the plurality of second openings OP2. The plurality of grooves may be understood to be formed by the standing wave described with reference to FIG. 10C. The plurality of grooves may refer to a recessed portion of an unevenness formed on the internal side wall.

In an example embodiment, the second photoresist layer PR2 may include a positive or negative photoresist. In an example embodiment, the second photoresist layer PR2 may include a material different from that of the first photoresist layer PR1. The second photoresist layer PR2 may include, for example, a positive photoresist.

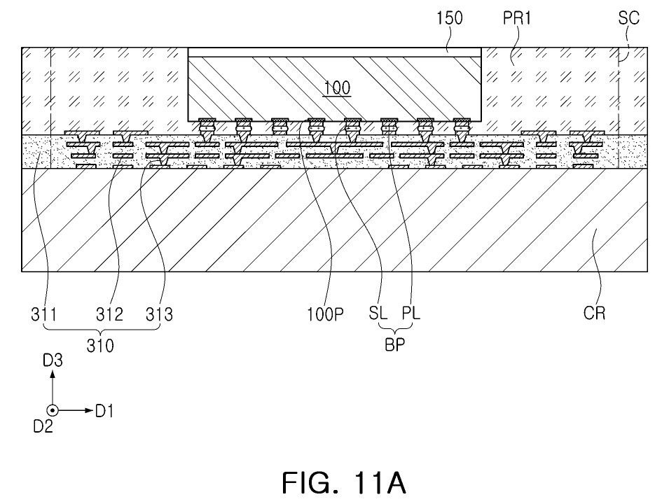

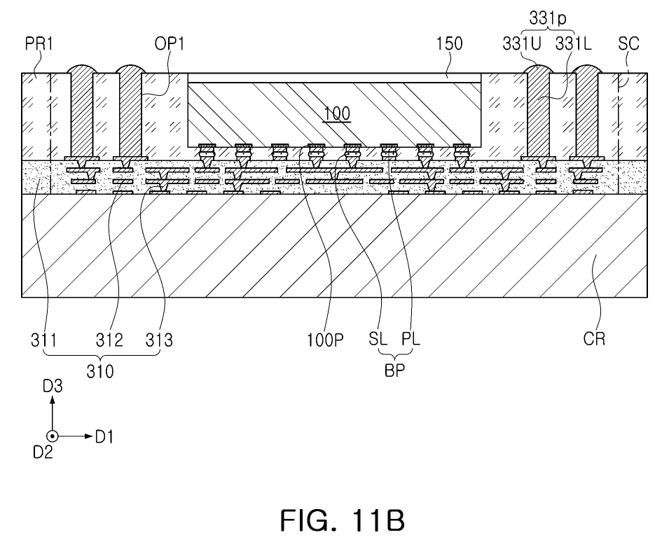

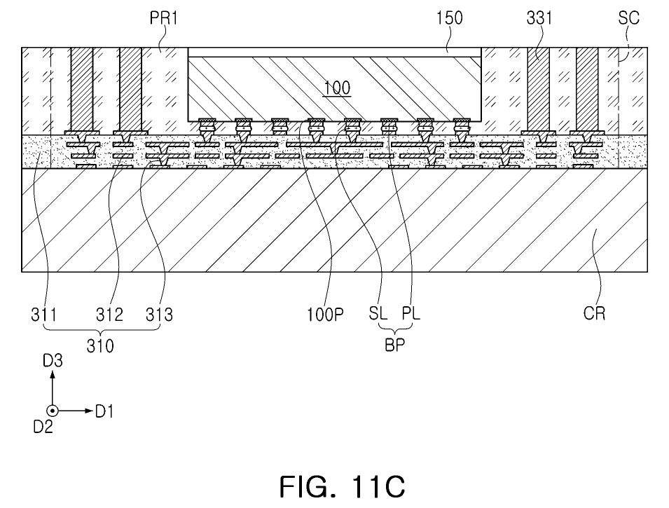

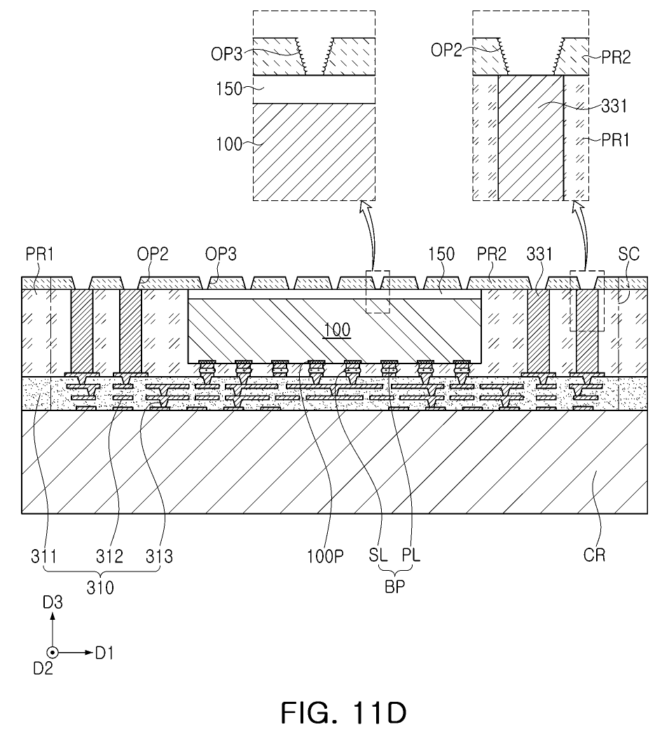

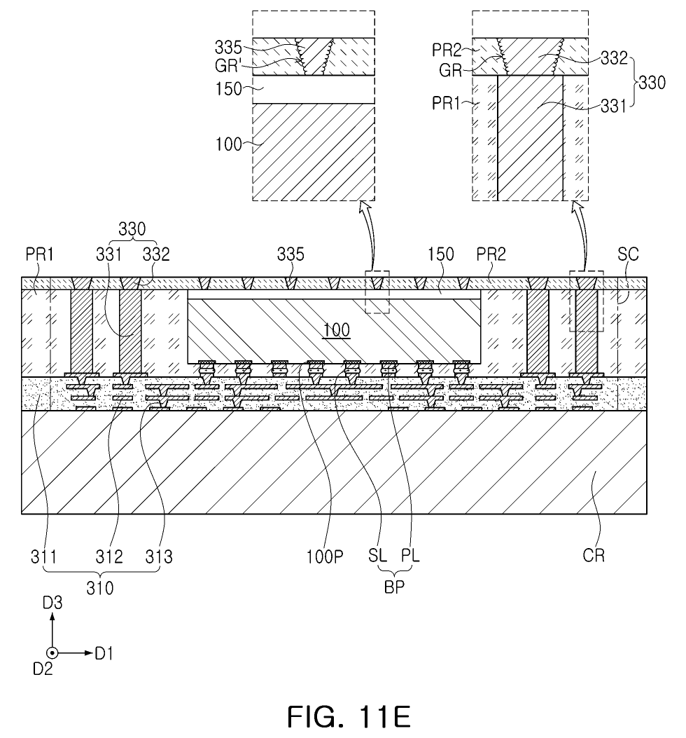

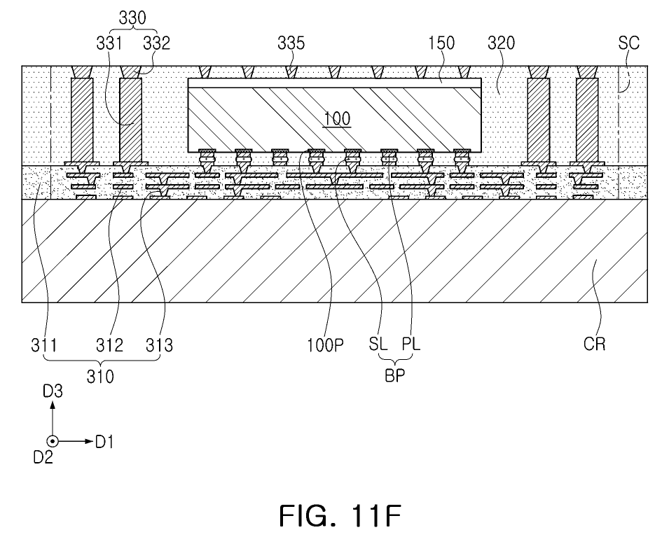

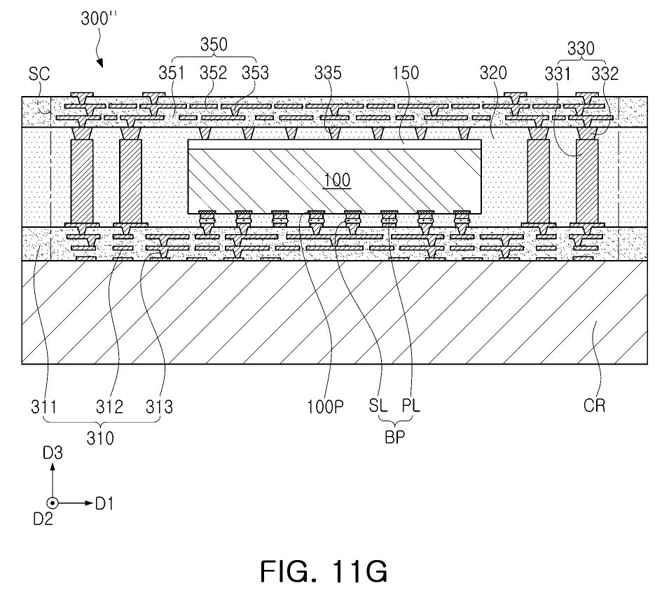

Referring to FIG. 10E, a plurality of upper metal layers 332 may be formed FIGS. 11A to 11G are cross-sectional diagrams illustrating processes of manufacturing a semiconductor package according to an example embodiment.

The plurality of second openings OP2 may be filled with a conductive material, and the upper metal layer 332 may be formed. The upper metal layer 332 may be formed by an electroplating process using the seed layer (see, e.g., seed layer 332’ in FIG. 2) in the plurality of second openings OP2. The seed layer may include titanium (Ti), copper (Cu), or the like.

The conductive material may fill the plurality of grooves. In another aspect, a plurality of grooves GR corresponding to the plurality of grooves may be formed on surfaces of the plurality of upper metal layers 332, respectively. Accordingly, a post 330 having a plurality of components having different degrees of surface roughness may be formed. For example, surface roughness of the side surface of the upper metal layer 332 may be greater than surface roughness of the side surface of the lower metal layer 331.

Referring to FIG. 10F, an encapsulant 320 may be formed.

The first and second photoresist layers PR1 and PR2 may be removed, and an encapsulant 320 may be formed on the lower redistribution structure 310. The encapsulant 320 may cover the chip structure 100 and the posts 330. The encapsulant 320 may include, for example, an EMC, and may be formed by a molded underfill (MUF) process.

Referring to FIG. 10G, an upper redistribution structure 350 may be formed on the encapsulant 320. The upper redistribution structure 350 may include an upper insulating layer 351, an upper redistribution layer 352, and an upper redistribution via 353. Thereafter, the unit packages 300’ may be isolated by cutting the lower redistribution structure 310, the encapsulant 320, and the upper redistribution structure 350 along a scribe lane SC.

Referring to FIG. 11A, a chip structure 100 may be mounted on a lower redistribution structure 310. A cover layer 150 may be disposed on one surface of the chip structure 100. The lower redistribution structure 310 may be formed on a carrier substrate CR. A first photoresist layer PR1 may be formed on the lower redistribution structure 310, the chip structure 100, and the cover layer 150.

A chip structure 100 may be formed on the lower redistribution structure 310. A cover layer 150 may be formed on an upper surface of the chip structure 100.

The first photoresist layer PR1 may be formed to surround a side portion of the chip structure 100 on the lower redistribution structure 310. The upper surface of the first photoresist layer PR1 may be at substantially the same level as the upper surface of the cover layer 150 with respect to the upper surface of the lower redistribution structure 310.

The first photoresist layer PR1 may be formed through a spin coating process or other suitable coating method. The first photoresist layer PR1 may work as a mask for forming a portion of the post (e.g., post 330 in FIG. 3A). In an example embodiment, the first photoresist layer PR1 may include a positive or negative photoresist. In an example embodiment, the first photoresist layer PR1 may include a negative photoresist.

Referring to FIG. 11B, a plurality of preliminary lower metal layers 331p may be formed.

A plurality of first openings OP1 penetrating the first photoresist layer PR1 and exposing the upper surface of the lower redistribution layer 312 may be formed. The plurality of first openings OP1 may be formed by the first exposure process and the first development process.

A conductive material may be filled in the plurality of first openings OP1, such that a lower portion 331L filling the plurality of first openings OP1 and an upper portion 331U on the first photoresist layer PR1 may be formed. In example embodiments, the upper surface of the lower portion 331L may be substantially at the same level as the upper surface of the cover layer 150.

A preliminary lower metal layer 331p may be formed by an electroplating process using a seed layer (see, e.g., seed layer 331’ in FIG. 4) in the plurality of first openings OP1. The seed layer may include titanium (Ti), copper (Cu), or the like.

Referring to FIG. 11C, a plurality of lower metal layers 331 may be formed.

Referring to FIGS. 11B and 11C together, a planarization process may be applied to remove the upper portion 331U and to allow the upper surface of the first photoresist layer PR1 to be substantially coplanar. The planarization process may include a grinding process, a chemical mechanical polishing (CMP) process, or the like, but an example embodiment thereof is not limited thereto.

Planarizing the upper surface of the first photoresist layer PR1 may be understood as generating a standing wave in the second exposure process to form a second opening (e.g., second opening OP2 in FIG. 11D) penetrating the second photoresist layer (e.g., second photoresist layer PR2 in FIG. 11D). For example, planarizing the upper surface of the first photoresist layer PR1 may be advantageous in generating the standing wave.

Referring to FIG. 11D, a second photoresist layer PR2 may be formed on the first photoresist layer PR1 and a plurality of lower metal layers 331.

A plurality of second openings OP2 penetrating the second photoresist layer PR2 and exposing the upper surface of the lower metal layer 331 may be formed. A plurality of third openings OP3 penetrating the second photoresist layer PR2 and exposing the upper surface of the cover layer 150 may be formed. The plurality of second and third openings OP2 and OP3 may be formed by the second exposure process and the second development process.

Each of the plurality of third openings OP3 may be spaced apart from each other in the first and second directions D1 and D2. In an example embodiment, each of the plurality of third openings OP3 may extend in the second direction (e.g., D2) and may be spaced apart from each other in the first direction (e.g., D1) (see FIG. 5).

A width of the lower surface of each of the plurality of second openings OP2 may be smaller than a width of the upper surface of the lower metal layer 331. Each of the plurality of second openings OP2 may have a width increasing from the lower region to the upper region. For example, the plurality of second openings OP2 may have an inverted trapezoidal shape in terms of cross-sectional area.

Each of the plurality of third openings OP3 may have a width increasing from the lower region to the upper region. For example, the plurality of third openings OP3 may have an inverted trapezoidal shape in terms of cross-sectional area.

A plurality of grooves may be formed on an internal side wall of each of the plurality of second and third openings OP2 and OP3. The plurality of grooves may be understood to be formed by the standing wave described with reference to FIG. 11C. The plurality of grooves may refer to a recessed portion of an unevenness formed on the internal side wall.

In an example embodiment, the second photoresist layer PR2 may include a positive or negative photoresist. In an example embodiment, the second photoresist layer PR2 may include a material different from that of the first photoresist layer PR1. The second photoresist layer PR2 may include, for example, a positive photoresist.

Referring to FIG. 11E, a plurality of upper metal layers 332 and a plurality of dummy via structure 335 may be formed.

The plurality of second and third openings OP2 and OP3 may be filled with a conductive material, and the upper metal layer 332 and the dummy via structure 335 may be formed. The upper metal layer 332 may be formed by an electroplating process using a seed layer (see, e.g., seed layer 332’ in FIG. 4) in the plurality of second openings OP2. The dummy via structure 335 may be formed by an electroplating process using a seed layer (see, e.g., seed layer 335’ in FIG. 4) in the plurality of third openings OP3. The seed layers may include titanium (Ti), copper (Cu), or the like.

The conductive material may fill the plurality of grooves. In another aspect, a plurality of grooves GR corresponding to the plurality of grooves may be formed on surfaces of the plurality of upper metal layers 332, respectively. A plurality of grooves GR’ corresponding to the plurality of grooves may be formed on surfaces of the plurality of dummy via structures 335, respectively.

Referring to FIG. 11F, an encapsulant 320 may be formed.

The first and second photoresist layers PR1 and PR2 may be removed, and an encapsulant 320 may be formed on the lower redistribution structure 310. The encapsulant 320 may cover the chip structure 100, the cover layer 150, the posts 330, and the dummy structures 335. The encapsulant 320 may include, for example, an EMC, and may be formed by a molded underfill (MUF) process.

Referring to FIG. 11G, an upper redistribution structure 350 may be formed on the encapsulant 320.

The upper redistribution structure 350 may include an upper insulating layer 351, an upper redistribution layer 352, and an upper redistribution via 353. Thereafter, the lower redistribution structure 310, the encapsulant 320, and the upper redistribution structure 350 may be cut along the scribe lane SC, thereby isolating the unit packages 300’’.

According to the aforementioned example embodiments, a semiconductor package having improved reliability and a method of manufacturing the same may be provided.

Specifically, by including a post having lower and upper metal layers having different widths, a semiconductor package having improved reliability may be provided. Also, by including a post having lower and upper metal layers having different degrees of surface roughness, a semiconductor package having improved reliability may be provided.

While the example embodiments have been illustrated and described above, it will be apparent to those skilled in the art that modifications and variations could be made without departing from the scope of the present disclosure as defined by the appended claims.

What is claimed is:

1. A semiconductor package, comprising:
a lower redistribution structure including a lower redistribution layer;
a lower chip structure on the lower redistribution structure;
an encapsulant covering the lower chip structure;
a post penetrating the encapsulant and connected to the lower redistribution layer; and
external connection bumps disposed below the lower redistribution structure and electrically connected to the lower redistribution layer,
wherein the post includes:
a first portion disposed on the lower redistribution layer of the lower redistribution structure and extending from the lower redistribution layer in a vertical direction; and
a second portion on the first portion,
wherein a width of a lower region of the second portion is smaller than a width of an upper region of the first portion, and
wherein a surface roughness of a side surface of the second portion is greater than a surface roughness of a side surface of the first portion.

2. The semiconductor package of claim 1, wherein the second portion has a shape having a width increasing from the lower region of the second portion to the upper region of the second portion.

3. The semiconductor package of claim 1, wherein a ratio of a width of an upper surface of the second portion to a width of a lower surface of the second portion is in a range of about 1.5 to about 2.0.

4. The semiconductor package of claim 1, wherein an angle formed by an upper surface of the second portion and a side surface of the second portion is in a range of about 30° to about 60°.

5. The semiconductor package of claim 1, wherein a ratio of a length of the first portion to a length of the second portion is in a range of about 2.0 to about 8.0 times in the vertical direction.

6. The semiconductor package of claim 1,
wherein the lower chip structure has a lower surface on which connection terminals are disposed, and
wherein the semiconductor package further includes connection bumps connecting the connection terminals to the lower redistribution layer.

7. The semiconductor package of claim 6, wherein each of the connection bumps includes:
a pillar portion in contact with the connection terminals; and
a solder portion disposed below the pillar portion.

8. The semiconductor package of claim 1, further comprising:
an upper chip structure disposed on the encapsulant and having a lower surface on which a connection terminal is disposed; and
a connection bump disposed between the connection terminal of the upper chip structure and the second portion of the post and electrically connecting the connection terminal to the second portion.

9. The semiconductor package of claim 1, wherein the lower chip structure includes:
a base chip including connection pads electrically connected to the lower redistribution layer, upper pads opposing the connection pads, and through-vias electrically connecting the connection pads to the upper pads; and
at least one stack chip disposed on the base chip, electrically connected to the base chip, and having a lower surface on which lower pads are disposed.

10. The semiconductor package of claim 9, wherein the lower chip structure further includes connection bumps disposed between the base chip and the at least one stack chip, the connection bumps electrically connecting the upper pads of the base chip to the lower pads of the at least one stack chip.

11. The semiconductor package of claim 9, wherein the upper pads of the base chip and the lower pads of the at least one stack chip are in direct contact with each other.

12. The semiconductor package of claim 1, further comprising:
an upper redistribution structure disposed on the encapsulant and including a plurality of upper redistribution layers and upper redistribution vias electrically connecting the plurality of upper redistribution layers to each other,
wherein the second portion of the post electrically connects the first portion to a first upper redistribution via positioned in a lowermost portion of the upper redistribution vias.

13. The semiconductor package of claim 12, wherein a width of a lower region of the first upper redistribution via is smaller than a width of an upper region of the second portion.

14. A semiconductor package, comprising:
a lower redistribution structure including a lower redistribution layer;
a chip structure on the lower redistribution structure;
an encapsulant covering the chip structure;
an upper redistribution structure disposed on the encapsulant, and including an upper insulating layer, and an upper redistribution layer and an upper redistribution via in the upper insulating layer;
a plurality of posts penetrating the encapsulant and electrically connecting the lower redistribution layer and the upper redistribution layer; and
external connection bumps disposed below the lower redistribution structure and electrically connected to the lower redistribution layer,
wherein each of the plurality of posts includes:
a lower metal layer on the lower redistribution layer of the lower redistribution structure; and
an upper metal layer disposed between the lower metal layer and the upper redistribution via, and electrically connecting the lower metal layer and the upper redistribution via,
wherein a width of the upper metal layer increases in a vertical direction, and a surface of the upper metal layer has a plurality of grooves,
wherein a width of a lower region of the upper metal layer is smaller than a width of an upper region of the lower metal layer, and
wherein at least a portion of the encapsulant fills the plurality of grooves of the upper metal layer.

15. The semiconductor package of claim 14, wherein the upper insulating layer of the upper redistribution structure covers an edge of the upper metal layer of each of the plurality of posts and the encapsulant.

16. The semiconductor package of claim 14, further comprising:
a cover layer including a first surface in contact with the chip structure, and a second surface opposite to the first surface; and
a plurality of via structures between a lower surface of the upper insulating layer of the upper redistribution structure and the second surface of the cover layer.

17. The semiconductor package of claim 16, wherein a width of each of the plurality of via structures is smaller than a width of the upper metal layer of each of the plurality of posts.

18. The semiconductor package of claim 16, wherein the plurality of via structures and the upper metal layer of the plurality of posts include the same material.

19. A semiconductor package, comprising:
a lower redistribution structure including a lower redistribution layer;
a chip structure on the lower redistribution structure;
an upper redistribution structure disposed on the chip structure and including an upper redistribution layer;
at least one post electrically connecting the lower redistribution layer to the upper redistribution layer on at least one side of the chip structure; and
an encapsulant covering the chip structure and the at least one post between the lower redistribution structure and the upper redistribution structure,
wherein the at least one post includes:
a lower metal layer on the lower redistribution layer of the lower redistribution structure; and
an upper metal layer disposed between the lower metal layer and the upper redistribution layer, and electrically connecting the lower metal layer and the upper redistribution layer,
wherein a surface of the upper metal layer has a plurality of grooves, and
wherein the encapsulant includes:
a first portion covering a back surface of the chip structure; and
a second portion extending in a horizontal direction from at least a portion of the first portion, filling the plurality of grooves of the upper metal layer of the post, covering an edge of an upper surface of the lower metal layer of the post, and surrounding at least a portion of a side surface of the lower metal layer of the at least one post.

20. The semiconductor package of claim 19, wherein the encapsulant further includes a third portion extending from the second portion toward an upper surface of the lower redistribution structure and surrounding a portion of a side surface of the chip structure and the side surface of the lower metal layer of the at least one post.
